(19) United States
(12) Patent Application Publication
(10) Pub. No.: US 2026/0362776 A1
(43) Pub. Date: Nov. 12, 2026

(54) SEMICONDUCTOR DEVICE AND METHOD FOR MANUFACTURING THE SAME

(71) Applicant: Kioxia Corporation, Tokyo (JP)

(72) Inventors: Soichi HOMMA, Yokkaichi Mie (JP); Yuusuke TAKANO, Yokkaichi Mie (JP)

(21) Appl. No.: 19/562,648

(22) Filed: Mar. 10, 2026

(30) Foreign Application Priority Data
May 8, 2025 (JP) 2025-078274

(51) Int. Cl. H10D 64/27; H10B 43/50; H10D 64/01

(52) U.S. Cl. CPC H10D 64/514; H10B 43/50; H10D 64/021

(57) ABSTRACT

A semiconductor device includes a first semiconductor chip that has a first surface and a second semiconductor chip that has a second surface facing and in contact with the first surface. The first and second semiconductor chips include, respectively, first and second metal pads, first and second inorganic insulating films, and first and second organic insulating films, on the first and second surfaces, respectively. The first metal pad and the second metal pad are bonded to each other. The first and second inorganic insulating films are in contact with each other. The first and second organic insulating films are in contact with each other. The first and second metal pads are in contact with the second and first inorganic insulating films, respectively. The first and second inorganic insulating films are in contact with the second and first organic insulating films, respectively.

### CROSS-REFERENCE TO RELATED APPLICATIONS

This application is based upon and claims the benefit of priority from Japanese Patent Application No. 2025-078274, filed May 8, 2025, the entire contents of which are incorporated herein by reference.

### FIELD

Embodiments described herein relate generally to a semiconductor device and a method for manufacturing the same.

### BACKGROUND

A semiconductor device may be manufactured by bonding a semiconductor chip with another semiconductor chip, bonding a semiconductor chip with a semiconductor wafer, or bonding a semiconductor wafer with another semiconductor wafer. However, for example, any foreign matter adhering between a semiconductor chip and a semiconductor chip may prevent the bonding from being properly achieved, which may cause voids and lead to detachment.

### BRIEF DESCRIPTION OF THE DRAWINGS

FIG. 1 illustrates a cross-sectional view of one example of a structure of a semiconductor device.

FIG. 2 illustrates a cross-sectional view of one example of a structure of a columnar part.

FIG. 3 illustrates a cross-sectional view of one example of a configuration of a semiconductor device according to a first embodiment.

FIGS. 4A-4M are cross-sectional diagrams to describe one example of a manufacturing method for the semiconductor device according to the first embodiment.

FIG. 5 illustrates a cross-sectional view of one example of a configuration of a semiconductor device according to a second embodiment.

FIG. 6 illustrates a cross-sectional view of one example of a configuration of a semiconductor device according to a third embodiment.

FIG. 7 illustrates a cross-sectional view of one example of a configuration of a semiconductor device according to a first modification of the third embodiment.

FIGS. 8A and 8B are cross-sectional diagrams to describe one example of a manufacturing method for a semiconductor device according to a fourth embodiment.

FIG. 9 illustrates a cross-sectional view of one example of a configuration of a semiconductor device according to a fifth embodiment.

FIG. 10 illustrates a cross-sectional view of one example of a configuration of a semiconductor device according to a first modification of the fifth embodiment.

FIG. 11 illustrates a cross-sectional view of one example of a configuration of a semiconductor device according to a second modification of the fifth embodiment.

FIG. 12 illustrates a cross-sectional view of one example of a configuration of a semiconductor device according to a sixth embodiment.

FIG. 13 illustrates a cross-sectional view of one example of a configuration of a semiconductor device according to a first modification of the sixth embodiment.

FIG. 14 illustrates a plan view of one example of a configuration of a semiconductor device according to a seventh embodiment.

FIG. 15 illustrates a plan view of one example of a configuration of a semiconductor device according to a first modification of the seventh embodiment.

### DETAILED DESCRIPTION

A semiconductor device and a method for manufacturing a semiconductor device in which bonding can be more properly achieved are provided.

In general, according to an embodiment, a semiconductor device includes a first semiconductor chip that has a first surface and a second semiconductor chip that has a second surface and is bonded to the first semiconductor chip with the first surface and the second surface facing and in contact with each other. The first semiconductor chip includes a first metal pad, a first inorganic insulating film, and a first organic insulating film that forms at least a part of the first surface. The second semiconductor chip includes a second metal pad, a second inorganic insulating film, and a second organic insulating film that forms at least a part of the second surface. The first metal pad and the second metal pad are bonded to each other. The first inorganic insulating film and the second inorganic insulating film are in contact with each other. The first organic insulating film and the second organic insulating film are in contact with each other. The first metal pad and the second inorganic insulating film are in contact with each other, and the second metal pad and the first inorganic insulating film are in contact with each other. The first inorganic insulating film and the second organic insulating film are in contact with each other, and the second inorganic insulating film and the first organic insulating film are in contact with each other.

Hereinafter, embodiments according to the present invention will be explained with reference to the drawings. The embodiments are not intended to limit the present invention. The drawings are schematically or conceptually shown, and the ratio between components or the like is not necessarily identical to the actual one. Throughout the description and the drawings, the same components as those mentioned prior thereto in connection with drawings mentioned prior thereto, are denoted by the same reference numerals, and the detailed explanation thereof will be omitted, as appropriate.

### First Embodiment

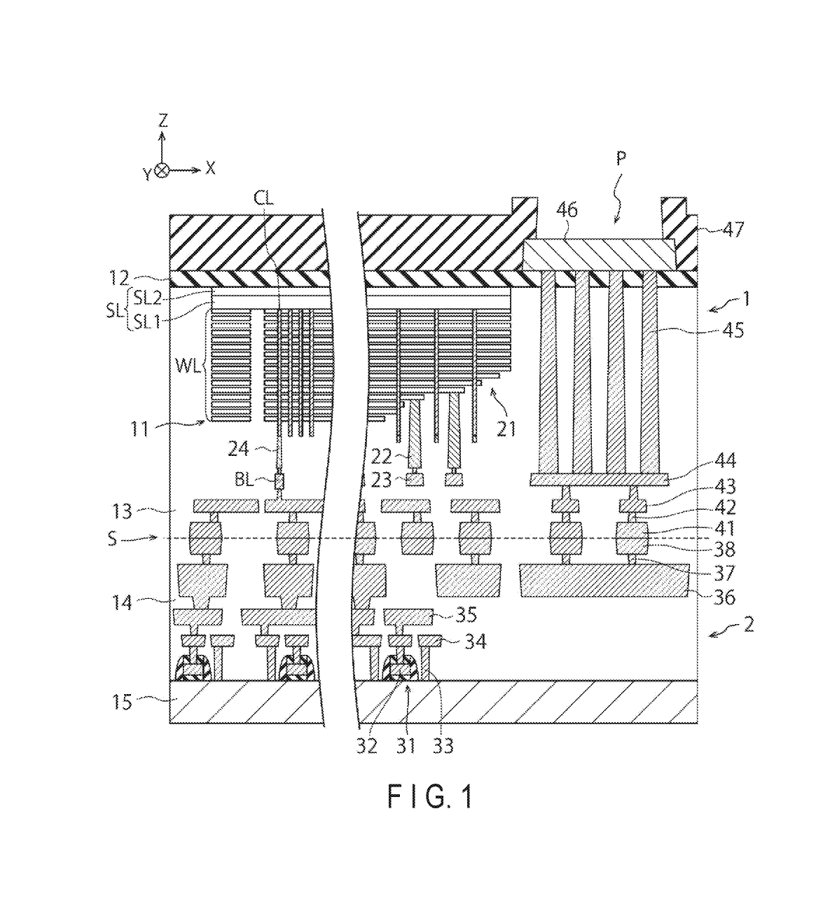

FIG. 1 illustrates a cross-sectional view of one example of a structure of a semiconductor device. The semiconductor device in FIG. 1 is a three-dimensional memory with an array chip 1 and a circuit chip 2 bonded together. The array chip 1 is an example of the first chip. The circuit chip 2 is an example of the second chip.

The array chip 1 includes a memory cell array 11 that includes multiple memory cells, an insulating film 12 arranged above the memory cell array 11, and an interlayer insulating film 13 arranged under the memory cell array 11. The insulating film 12 is, for example, a silicon oxide or silicon nitride film. The interlayer insulating film 13 is, for example, a silicon oxide film, or a stacked film including a silicon oxide film and any other insulating film.

The circuit chip 2 is arranged under the array chip 1. Reference character S denotes a bonding surface between the array chip 1 and the circuit chip 2. The bonding surface S is an example of the first bonding surface. The circuit chip 2 includes an interlayer insulating film 14 and a substrate 15 arranged under the interlayer insulating film 14. The interlayer insulating film 14 is, for example, a silicon oxide film, or a stacked film including a silicon oxide film and any other insulating film. The substrate 15 is, for example, a semiconductor substrate such as a silicon substrate.

In FIG. 1, X and Y directions are parallel with a surface of the substrate 15 and are perpendicular to each other, and a Z direction is perpendicular to a surface of the substrate 15. Here, the +Z direction is taken as the upper direction while the -Z direction is taken as the lower direction. The -Z direction may coincide with the gravity direction or may not coincide with the gravity direction.

The array chip 1 includes multiple word lines WL and a source line SL as electrode layers of the memory cell array 11. In FIG. 1, a stair structure part 21 of the memory cell array 11 is shown. Each word line WL is electrically connected to a word wiring layer 23 via a contact plug 22. Each columnar part CL passing through the multiple word lines WL is electrically connected to a bit line BL via a via plug 24, and further electrically connected to the source line SL. The source line SL includes a first layer SL1 which is a semiconductor layer, and a second layer SL2 which is a metal layer.

The circuit chip 2 includes multiple transistors 31. Each transistor 31 includes a gate electrode 32 that is arranged on the substrate 15 via a gate insulating film, and a source diffusion layer and a drain diffusion layer (not shown) that are located in the substrate 15. Further, the circuit chip 2 includes multiple contact plugs 33 that are arranged on the gate electrodes 32 and the source or drain diffusion layers of the transistors 31, a wiring layer 34 that is arranged on the contact plugs 33 and includes multiple wirings, and a wiring layer 35 that is arranged on the wiring layer 34 and includes multiple wirings.

The circuit chip 2 further includes a wiring layer 36 that is arranged on the wiring layer 35 and includes multiple wirings, multiple via plugs 37 that are arranged on the wiring layer 36, and multiple metal pads 38 that are arranged on the via plugs 37. The metal pads 38 are, for example, Cu (copper) layers or Al (aluminum) layers. The circuit chip 2 functions as a control circuitry (logic circuitry) that controls operation of the array chip 1. The control circuitry is formed of the transistors 31, etc. and is electrically connected to the metal pads 38.

The array chip 1 includes multiple metal pads 41 that are arranged on the metal pads 38, and multiple via plugs 42 that are arranged on the metal pads 41. Further, the array chip 1 includes a wiring layer 43 that is arranged on the via plugs 42 and includes multiple wirings, and a wiring layer 44 that is arranged on the wiring layer 43 and includes multiple wirings. The metal pads 41 are, for example, Cu layers or Al layers.

The array chip 1 further includes multiple via plugs 45 that are arranged on the wiring layer 44, a metal pad 46 that is arranged on the via plugs 45 and on the insulating film 12, and a passivation film 47 that is arranged on the metal pad 46 and on the insulating film 12. The metal pad 46 is, for example, a Cu layer or an Al layer, and functions as an external connection pad (bonding pad) of the semiconductor device of FIG. 1. The passivation film 47 is, for example, an insulating film such as a silicon oxide film, and has an opening P from which the upper surface of the metal pad 46 is exposed. Through the opening P, the metal pad 46 can be connected to a mounting substrate and other devices with a boding wire, a solder ball, a metal bump, or the like.

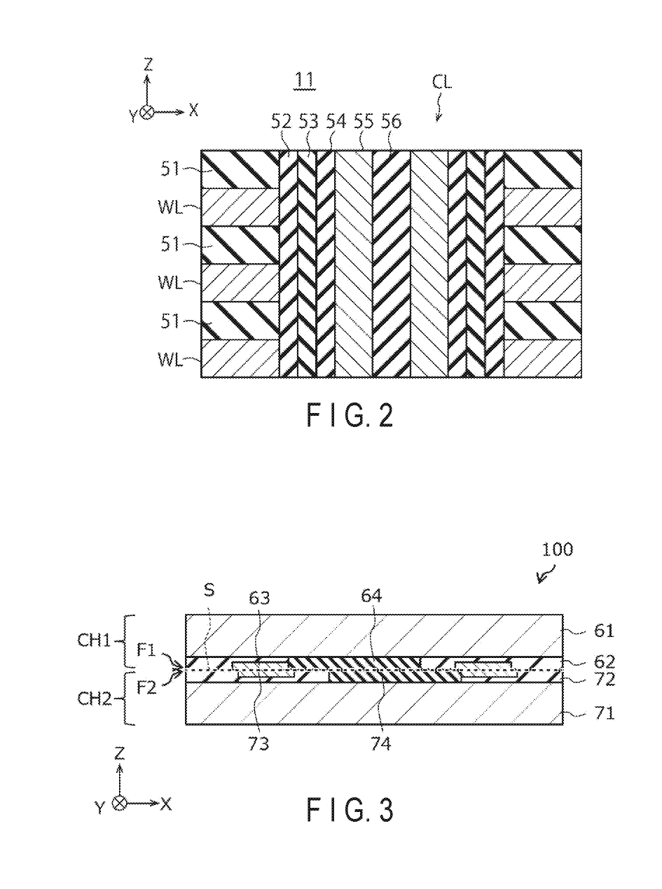

FIG. 2 illustrates a cross-sectional view of one example of a structure of the columnar part CL.

As shown in FIG. 2, the memory cell array 11 includes multiple word lines WL and multiple insulating layers 51 alternately stacked on the interlayer insulating film 13 (FIG. 1). The word lines WL are, for example, W (tungsten) layers. The insulating layers 51 are, for example, silicon oxide films.

The columnar part CL includes a block insulating film 52, a charge storage layer 53, a tunnel insulating film 54, a channel semiconductor layer 55, and a core insulating film 56 in this order. The charge storage layer 53 is, for example, a silicon nitride film, and is formed on side surfaces of the word lines WL and the insulating layers 51 via the block insulating film 52. The charge storage layer 53 may be a semiconductor layer such as a polysilicon layer. The channel semiconductor layer 55 is, for example, a polysilicon layer, and is formed on a side surface of the charge storage layer 53 via the tunnel insulating film 54. The block insulating film 52, the tunnel insulating film 54, and the core insulating film 56 are, for example, silicon oxide films or metal insulating films.

FIG. 3 illustrates a cross-sectional view of one example of a configuration of a semiconductor device 100 according to the first embodiment.

The semiconductor device 100 includes a semiconductor chip CH1 and a semiconductor chip CH2.

The semiconductor chip CH1 and the semiconductor chip CH2 are bonded together. Each of the semiconductor chip CH1 and the semiconductor chip CH2 may be, for example, a semiconductor such as a NAND flash memory or an LSI (Large Scale Integration). The semiconductor chip CH1 is, but not limited to, the array chip 1 shown in FIG. 1, for example. The semiconductor chip CH2 is, but not limited to, the circuit chip 2 shown in FIG. 1, for example.

The first semiconductor chip CH1 includes a surface F1, a substrate 61, an inorganic insulating film 62, a metal pad 63, and an organic insulating film 64.

The surface F1 is a bonding surface to a surface F2 of the semiconductor chip CH2.

The substrate 61 is, for example, a semiconductor substrate such as an Si (silicon) substrate. The semiconductor elements (not shown) including the memory cell array 11 are arranged under the substrate 61.

The inorganic insulating film 62 is arranged under the substrate 61. The inorganic insulating film 62 contains, for example, SiO2, SiN, SiF, SiOC, SiCN, SiCOH, Al2O3, or AlN.

The metal pad 63 is arranged under the inorganic insulating film 62. The metal pad 63 contains, for example, a low resistance metal such as a simple substance of Al, Cu, Au, Ag, Ni, Pd, W, Ti, Nb, Ru, Mo, Co, or Cr, a nitride thereof, a composite film of two or more thereof, or an alloy of two or more thereof.

The organic insulating film 64 is arranged under the substrate 61. For example, the organic insulating film 64 is arranged, on the surface F1, in a region where the inorganic insulating film 62 is not arranged. The organic insulating film 64 contains, for example, an epoxy-based, phenol-based, polyimide-based, polyamide-based, acrylic-based, polybenzoxazole (PBO)-based, silicone-based, or benzocyclobutene-based resin.

In the same plane, the metal pad 63, the inorganic insulating film 62, and the organic insulating film 64 are exposed from the surface F1 which is the bonding surface S.

The second semiconductor chip CH2 includes a surface F2, a substrate 71, an inorganic insulating film 72, a metal pad 73, and an organic insulating film 74.

The surface F2 is a bonding surface to the surface F1 of the semiconductor chip CH1.

The substrate 71 is, for example, a semiconductor substrate such as an Si (silicon) substrate. The semiconductor elements (not shown) including the transistors 31 are arranged on the substrate 71.

The inorganic insulating film 72 is arranged on the substrate 71. The inorganic insulating film 72 contains, for example, SiO2, SiN, SiF, SiOC, SiCN, SiCOH, Al2O3, or AlN.

The metal pad 73 is arranged on the inorganic insulating film 72. The metal pad 73 contains, for example, a low resistance metal such as a simple substance of Al, Cu, Au, Ag, Ni, Pd, W, Ti, Nb, Ru, Mo, Co, or Cr, a nitride thereof, a composite film of two or more thereof, or an alloy of two or more thereof.

The organic insulating film 74 is arranged on the substrate 71. For example, the organic insulating film 74 is arranged, on the surface F2, in a region where the inorganic insulating film 72 is not arranged. The organic insulating film 74 contains, for example, an epoxy-based, phenol-based, polyimide-based, polyamide-based, acrylic-based, polybenzoxazole (PBO)-based, silicone-based, or benzocyclobutene-based resin.

In the same plane, the metal pad 73, the inorganic insulating film 72, and the organic insulating film 74 are exposed from the surface F2 which is the bonding surface S.

The semiconductor chip CH1 and the semiconductor chip CH2 are bonded together with the surface F1 and the surface F2 facing each other.

The metal pads 63, 73 are bonded to each other. The inorganic insulating films 62, 72 are in contact with each other. The organic insulating films 64, 74 are in contact with each other. The metal pad 63 and the inorganic insulating film 72 are in contact (direct contact) with each other. The metal pad 73 and the inorganic insulating film 62 are in contact with each other. The inorganic insulating film 62 and the organic insulating film 74 are in contact with each other. The inorganic insulating film 72 and the organic insulating film 64 are in contact with each other.

In the first embodiment, the metal pad 63 and the organic insulating film 74 are in contact with each other. The metal pad 73 and the organic insulating film 64 are in contact with each other.

In the first embodiment, the inorganic insulating films 62, 72 are in contact with each other. If plasma treatment or addition of a hydroxyl group is performed, the inorganic insulating films 62, 72 can be bonded and reinforced. This can inhibit detachment more reliably.

Next, a manufacturing method for the semiconductor device 100 according to the first embodiment will be explained.

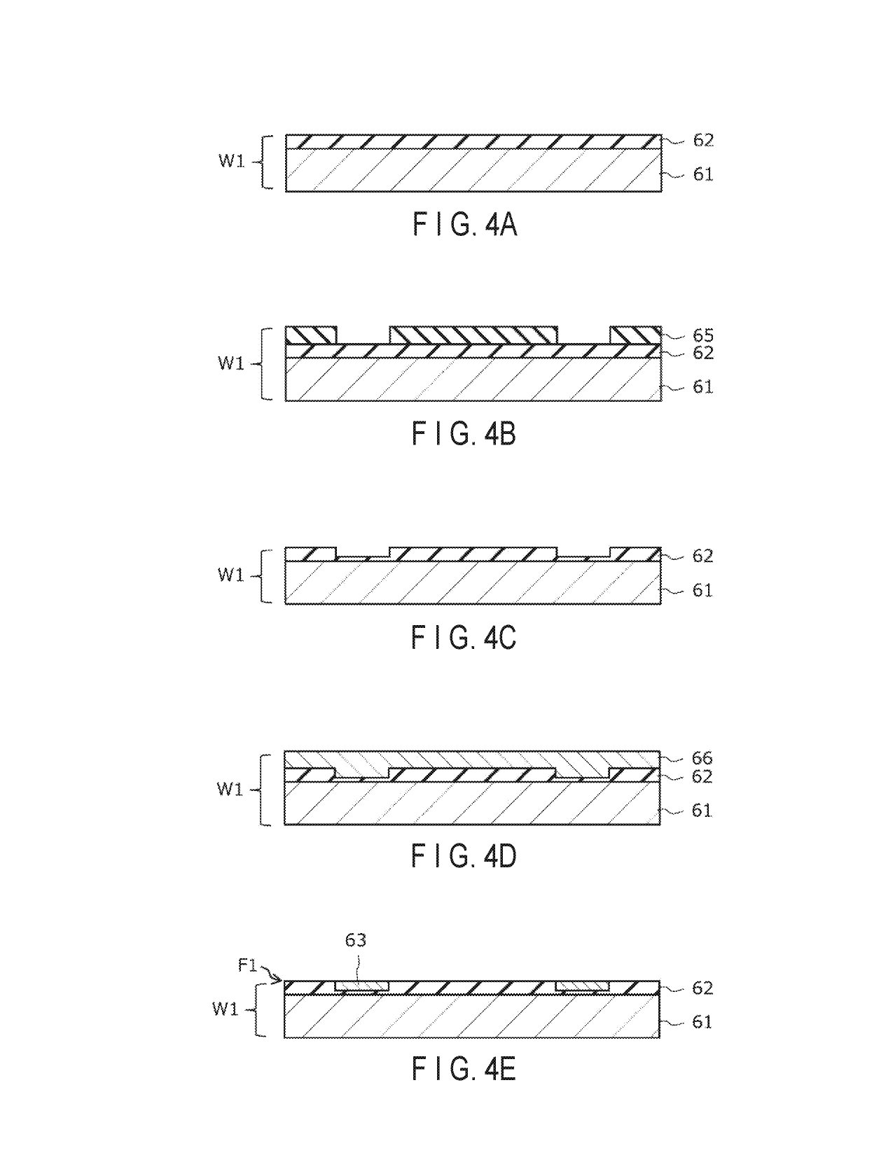

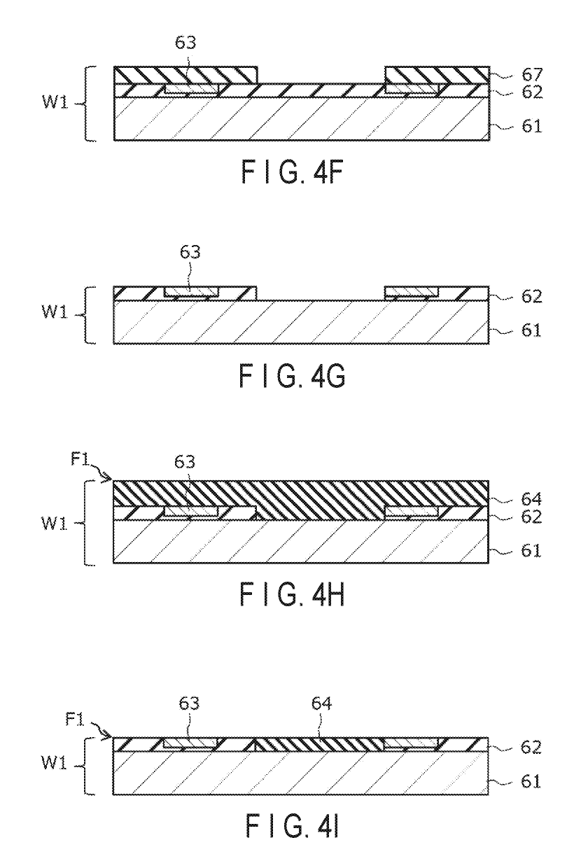

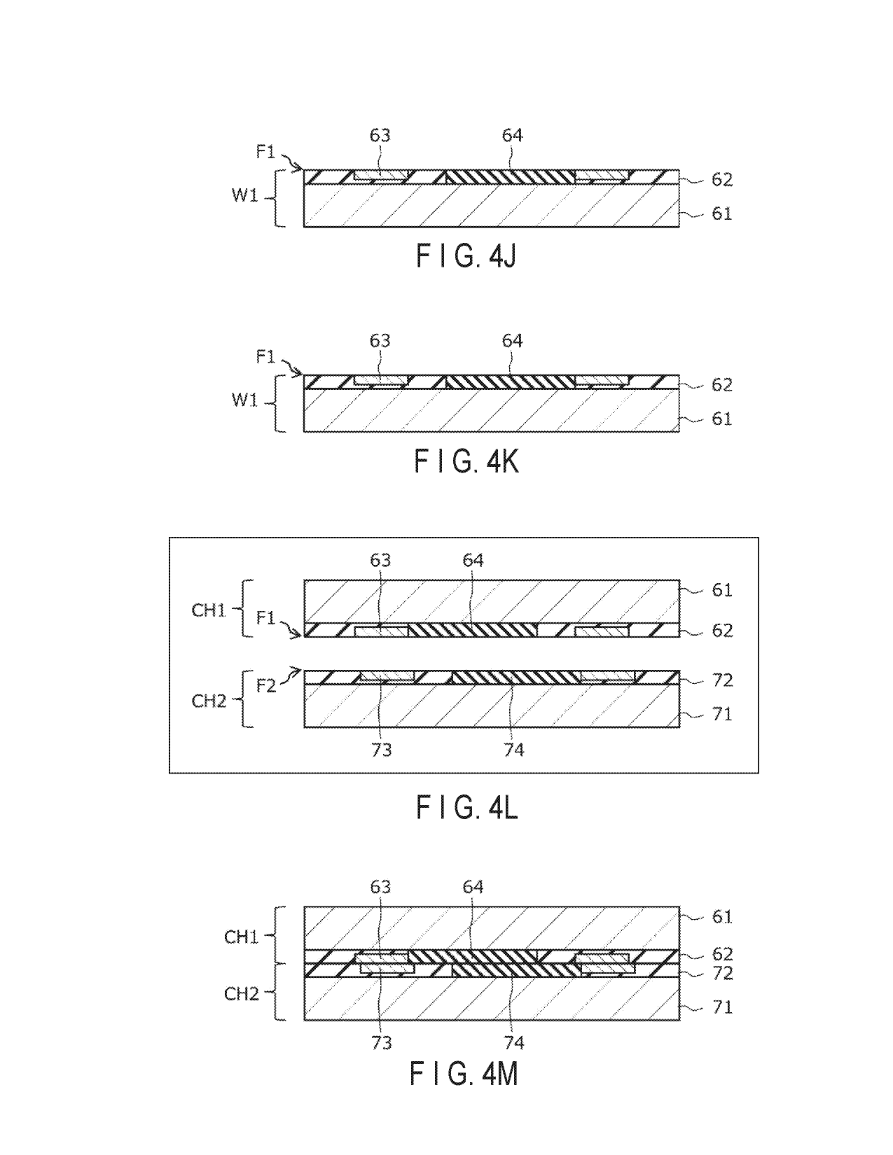

FIGS. 4A-4M are cross-sectional diagrams each showing one example of a process step of the manufacturing method for the semiconductor device 100 according to the first embodiment. The semiconductor chip CH1 is illustrated in FIGS. 4A-4K, but the same applies to the semiconductor chip CH2. In FIGS. 4A-4K, part of a wafer W prior to singulation to the semiconductor chip CH1 is shown.

First, as shown in FIG. 4A, a semiconductor element is formed on the substrate 61, and the inorganic insulating film 62 is formed on the semiconductor element. The inorganic insulating film 62 contains, for example, SiO2, SiN, SiF, SiOC, SiCN, SiCOH, Al2O3, or AlN.

Next, as shown in FIG. 4B, a protective film 65 is formed on the inorganic insulating film 62, and an opening is formed in the protective film 65. The opening is formed by, for example, exposure and development. The opening is formed in a prescribed pattern for forming the metal pad 63. The protective film 65 protects the inorganic insulating film 62 in a later step. The protective film 65 is, for example, a resist, an insulating film, or the like.

Next, as shown in FIG. 4C, the inorganic insulating film 62 is etched using the protective film 65 as a mask. The etching of the inorganic insulating film 62 is achieved by, for example, dry etching using plasma or wet etching using a chemical agent. Thereafter, the protective film 65 is removed.

Next, as shown in FIG. 4D, a metal seed layer is formed on the inorganic insulating film 62, and the opening of the inorganic insulating film 62 is filled with a metal film 66. The seed layer is formed by, for example, sputtering. The metal film 66 is formed by, for example, plating. The seed layer contains, for example, a low resistance metal such as a simple substance of Al, Cu, Au, Ag, Ni, Pd, W, Ti, Nb, Ru, Mo, Co, or Cr, a nitride thereof, a composite film of two or more thereof, or an alloy of two or more thereof. The metal film 66 contains, for example, a low resistance metal such as a simple substance of Al, Cu, Au, Ag, Ni, Pd, W, Ti, Nb, Ru, Mo, Co, or Cr, a nitride thereof, a composite film of two or mobre thereof, or an alloy of two or more thereof.

Next, as shown in FIG. 4E, the surface F1 (upper surface) is polished (planarized) so that the metal film 66 is removed to expose the inorganic insulating film 62. The polishing is achieved by, for example, mechanical polishing or CMP (Chemical Mechanical Polishing). Accordingly, a structure (metal pad 63) in which metal is embedded in the opening of the inorganic insulating film 62 is formed.

Next, as shown in FIG. 4F, a protective film 67 is formed on the inorganic insulating film 62, and an opening is formed in the protective film 67. The opening is formed by, for example, exposure and development. The opening is formed in a prescribed pattern for forming the organic insulating film 64. The protective film 67 protects the inorganic insulating film 62 in a later step. The protective film 67 is, for example, a resist, an insulating film, or the like.

Next, as shown in FIG. 4G, the inorganic insulating film 62 is etched using the protective film 67 as a mask. The etching of the inorganic insulating film 62 is achieved by, for example, dry etching using plasma or wet etching using a chemical agent. Thereafter, the protective film 67 is removed.

Next, as shown in FIG. 4H, the organic insulating film 64 is formed on the entire surface F1. The organic insulating film 64 uses, for example, an epoxy-based, phenol-based, polyimide-based, polyamide-based, acrylic-based, polybenzoxazole (PBO)-based, silicone-based, or benzocyclobutene-based resin.

Next, as shown in FIG. 4I, the surface F1 is polished so that the organic insulating film 64 is removed to expose the inorganic insulating film 62 and the metal pad 63. The polishing is achieved by, for example, mechanical polishing or CMP. Accordingly, a structure in which the organic insulating film 64 is embedded in the opening of the inorganic insulating film 62 is formed. Thus, the surface F1 is polished (planarized) so that the metal pad 63, the inorganic insulating film 62, and the organic insulating film 64 are exposed therefrom.

Next, as shown in FIG. 4J, plasma treatment is performed on the surface F1. The plasma treatment is performed using, for example, N2 plasma, Ar plasma, or O2 plasma. The plasma treatment may be performed using plasma containing two or more gases. For example, Ar+N2 plasma, Ar+O2 plasma, or the like may be used. Alternatively, combination of two or more kinds of plasma, for example, O2 plasma followed by N2 plasma, or Ar plasma followed by N2 plasma may be used. The surfaces of the inorganic insulating film 62 and the organic insulating film 64 are activated by the plasma so that the insulating films can be bonded to each other.

Next, as shown in FIG. 4K, addition of a hydroxyl group is performed on the surface F1. The addition of a hydroxyl group is achieved by, for example, addition of pure water. As a result of the addition of a hydroxyl group, the inorganic insulating films can be bonded to each other.

A wafer W2 is subjected to the same steps as FIGS. 4A-4K.

Next, as shown in FIG. 4L, the wafers W1, W2 are singulated into the semiconductor chips CH1, CH2, and the semiconductor chips CH1, CH2 are positioned and bonded together with the surface F1 and the surface F2 facing each other. The singulation is achieved by, for example, dicing or laser dicing. The positioning is achieved using, for example, a flip-chip bonder.

Next, as shown in FIG. 4M, annealing is performed to reinforce the bonding. As a result, the semiconductor device 100 shown in FIG. 1 is finished. The annealing is performed at 150 to 400° C. of the temperature for about 0.5 to 5 hours, for example. The annealing may be performed in the N2 atmosphere in order to prevent oxidation.

As described above, in the first embodiment, the semiconductor chip CH1 includes the metal pad 63, the inorganic insulating film 62, and the organic insulating film 64 that are exposed from the surface F1 in the same plane. The semiconductor chip CH2 includes the metal pad 73, the inorganic insulating film 72, and the organic insulating film 74 that are exposed from the surface F2 in the same plane. The semiconductor chips CH1, CH2 are bonded together with the surface F1 and the surface F2 facing each other. With the organic insulating films 64, 74, the bonding can be more properly achieved.

In a case where the organic insulating films 64, 74 are not arranged, an occupancyratio of the inorganic insulating film 62, 72 on the bonding surface S is high. If foreign matter adheres between the semiconductor chip CH1 and the semiconductor chip CH2, or between the inorganic insulating film 62 and the inorganic insulating film 72, there is a possibility that the bonding fails, or a possibility that generation of voids or the like causes detachment.

In contrast, in the first embodiment, if foreign matter adheres to the organic insulating film 64, 74, the bonding with the foreign matter can lead to suppression of voids or detachment.

### Second Embodiment

FIG. 5 illustrates a cross-sectional view of one example of a configuration of the semiconductor device 100 according to a second embodiment. The second embodiment differs from the first embodiment in that the metal pad 63 and the organic insulating film 74 are not in contact with each other, and the metal pad 73 and the organic insulating film 64 are not in contact with each other. In other words, the metal pad 63 and the organic insulating layer 74 are apart from each other, and the metal pad 73 and the organic insulating film 64 are apart from each other.

The organic insulating film 64 is arranged apart from the metal pad 63. The organic insulating film 64 is not in contact with the metal pad 73.

The organic insulating film 74 is arranged apart from the metal pad 73. The organic insulating film 74 is not in contact with the metal pad 73.

The organic insulating films 64, 74 are likely to absorb moisture. If the organic insulating film 64, 74 is in contact with the metal pad 63, 73, the metal pad 63, 73 is oxidized by moisture absorbed by the organic insulating film 64, 74. Accordingly, defective adhesion is likely to occur. As a result, there is a possibility of occurrence of detachment at the interface between the organic insulating film 64, 74 and the metal pad 63, 73.

In contrast, in the second embodiment, the organic insulating film 64 is not in contact with the metal pad 73 and the organic insulating film 74 is not in contact with the metal pad 63. Accordingly, the metal pads 63, 73 can be inhibited from being oxidized by adsorbed moisture. As a result, detachment at the bonding interface can be suppressed.

In the second embodiment, in the steps shown in FIGS. 4F and 4G, the opening of the inorganic insulating film 62 is formed in a position for inhibiting the organic insulating film 64, 74 from contacting the metal pad 63, 73.

The metal pad 63 and the organic insulating film 74 may be not in contact with each other, and the metal pad 73 and the organic insulating film 64 may be not in contact with each other, as described in the second embodiment. With the semiconductor device 100 according to the second embodiment, the same effects as those provided by the first embodiment can be obtained.

### Third Embodiment

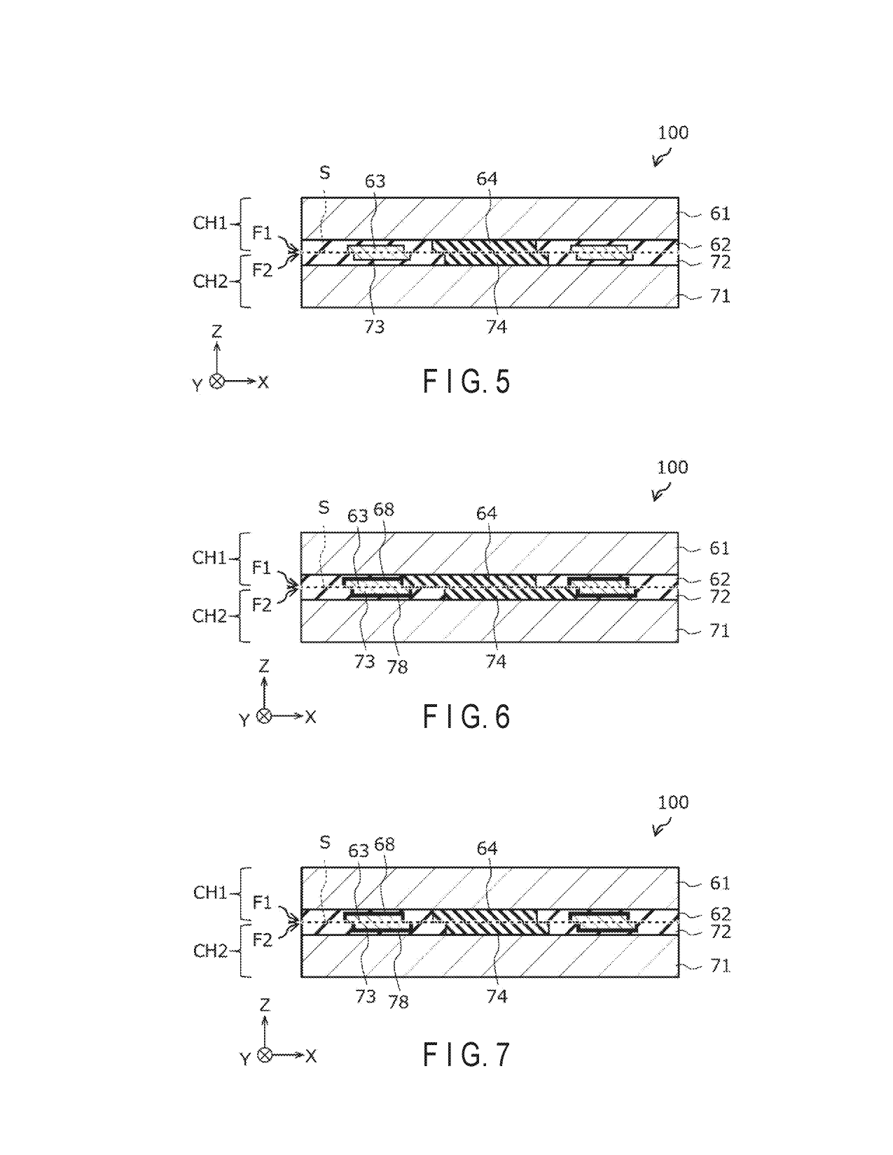

FIG. 6 illustrates a cross-sectional view of one example of a configuration of the semiconductor device 100 according to a third embodiment. The third embodiment differs from the first embodiment in that a barrier metal film is arranged.

The semiconductor chip CH1 further includes a barrier metal film 68. The barrier metal film 68 is arranged on an outer peripheral portion and an upper surface of the metal pad 63. The barrier metal film 68 is arranged between the metal pad 63 and the inorganic insulating film 62, and is exposed from the surface F1. The barrier metal film 68 is, for example, a simple substance of Ti, Cr, Ta, W, Nb, Ru, Mo, Co, or Pd, a nitride thereof, or a composite film of two or more of these simple substances and nitrides.

The semiconductor chip CH2 further includes a barrier metal film 78. The barrier metal film 78 is arranged on an outer peripheral portion and a bottom surface of the metal pad 73. The barrier metal film 78 is arranged between the metal pad 73 and the inorganic insulating film 72, and is exposed from the surface F2. The barrier metal film 78 is, for example, a simple substance of Ti, Cr, Ta, W, Nb, Ru, Mo, Co, or Pd, a nitride thereof, or a composite film of two or more of these simple substances and nitrides.

With the barrier metal films 68, 78, the adhesiveness between the inorganic insulating films 62, 72 and the metal pad 73 in the side surface direction can be improved. In addition, with the barrier metal film 68, contact between the metal pad 63 and the organic insulating film 64 can be inhibited. Also, with the barrier metal film 78, contact between the metal pad 73 and the organic insulating film 74 can be inhibited.

The barrier metal film 68 and the barrier metal film 78 are in contact with each other or bonded to each other. The metal pad 63 and the barrier metal film 78 are in contact with each other or bonded to each other. The metal pad 73 and the barrier metal film 68 are in contact with each other or bonded to each other. Depending on the materials of the barrier metal films 68, 78, the annealing temperature, etc., the metal pad and the barrier metal film facing each other may be bonded to each other, or may be in contact with each other without being bonded. The inorganic insulating film 62 and the barrier metal film 78 are in contact with each other. The inorganic insulating film 72 and the barrier metal film 68 are in contact with each other.

Further, in the third embodiment, the organic insulating film 64 and the barrier metal film 78 are in contact with each other. The organic insulating film 74 and the barrier metal film 68 are in contact with each other.

In the third embodiment, the barrier metal film 68 is formed before the step shown in FIG. 4D of the first embodiment. The barrier metal film 68 is formed by, for example, sputtering.

A barrier metal film may be arranged, as described in the third embodiment. With the semiconductor device 100 according to the third embodiment, the same effects as those provided by the first embodiment can be obtained.

### First Modification of Third Embodiment

FIG. 7 illustrates a cross-sectional view of one example of a configuration of the semiconductor device 100 according to a first modification of the third embodiment. The first modification of the third embodiment differs from the third embodiment in that the metal pad 63 (and the barrier metal film 68) is not in contact with the organic insulating film 74 and the metal pad 73 (and the barrier metal film 78) is not in contact with the organic insulating film 64. In other words, the metal pad 63 (and the barrier metal film 68) and the organic insulating layer 74 are apart from each other, and the metal pad 73 (and the barrier metal film 78) and the organic insulating film 64 are apart from each other. That is, the first modification of the third embodiment is combination of the third embodiment and the second embodiment.

The metal pad 63 (and the barrier metal film 68) may not be in contact with the organic insulating film 74, and the metal pad 73 (and the barrier metal film 78) may not be in contact with the organic insulating film 64, as described in the first modification of the third embodiment. With the semiconductor device 100 according to the first modification of the third embodiment, the same effects as those provided by the third embodiment can be obtained.

### Fourth Embodiment

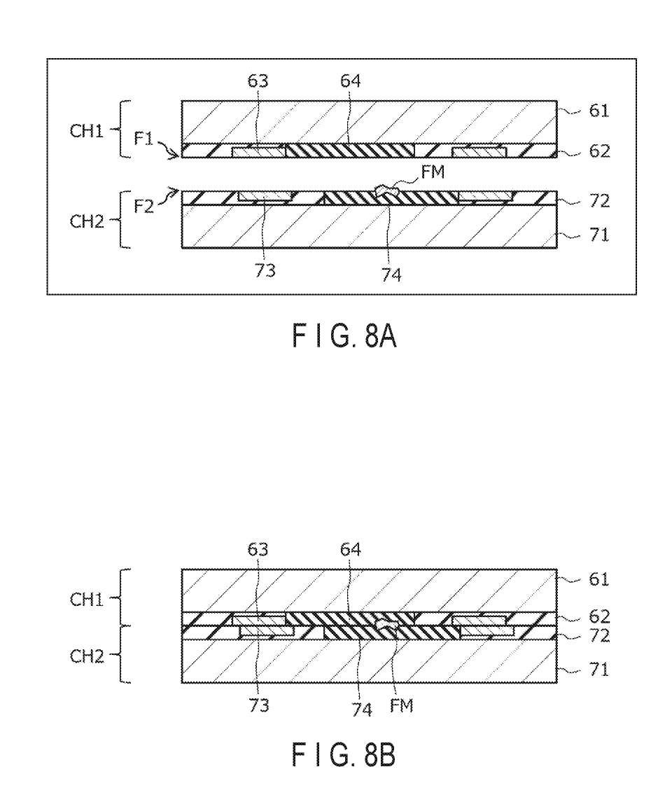

FIGS. 8A and 8B are cross-sectional diagrams each showing one example of a process step of a manufacturing method for the semiconductor device 100 according to a fourth embodiment. The fourth embodiment differs from the first embodiment in that foreign matter is taken in the organic insulating films 64, 74.

The steps shown in FIGS. 8A and 8B are equivalent to those shown in FIGS. 4L and 4M of the first embodiment.

After the addition of a hydroxyl group is performed on the surface F1 (see FIG. 4K), the wafer W1, W2 is singulated into the semiconductor chip CH1, CH2, and the semiconductor chips CH1, CH2 are positioned and bonded together with the surface F1 and the surface F2 facing each other. As shown in FIG. 8A, foreign matter FM adheres to the surface F1. More specifically, the foreign matter FM adheres to the organic insulating film 64. The foreign matter FM is, for example, particles derived from the substrates 61, 71 during dicing, but is not limited thereto.

Next, as shown in FIG. 8B, annealing is performed to reinforce the bonding. As shown in FIG. 8B, the foreign matter FM is taken and enclosed in the organic insulating films 64, 74. Accordingly, generation of voids and detachment can be suppressed. The foreign matter FM whose size is equal to or smaller than the film thickness of the organic insulating film 64, 74 in most cases, is taken in the organic insulating film 64, 74. A ratio of an area of the inorganic insulating film 62, 72 in the bonding surface (surfaces F1 and F2) divided by an area of the bonding surface excluding an area of the metal pad 63, 73 is, for example, 5 to 50%. Therefore, ana ratio of an area of the organic insulating film 64, 74 in the bonding surface (surfaces F1 and F2) divided by an area of the bonding surface excluding an area of the metal pad 63, 73 is, for example, 50 to 95%. As the ratio of the area of the organic insulating film 64, 74 is higher, generation of a defect caused by the foreign matter FM can be suppressed more reliably.

That is, the larger the proportion of the organic insulating films 64, 74 in the bonding surface, the more likely the foreign matter FM adhering to the bonding surface is taken in the organic insulating films 64, 74 even when the foreign matter FM adheres to the bonding surface. Accordingly, generation of voids or detachment is retarded. As a result, the bonding can be more properly achieved.

Foreign matter may be taken in the organic insulating films 64, 74, as described in the fourth embodiment. With the semiconductor device 100 according to the fourth embodiment, the same effects as those provided by the first embodiment can be obtained.

### Fifth Embodiment

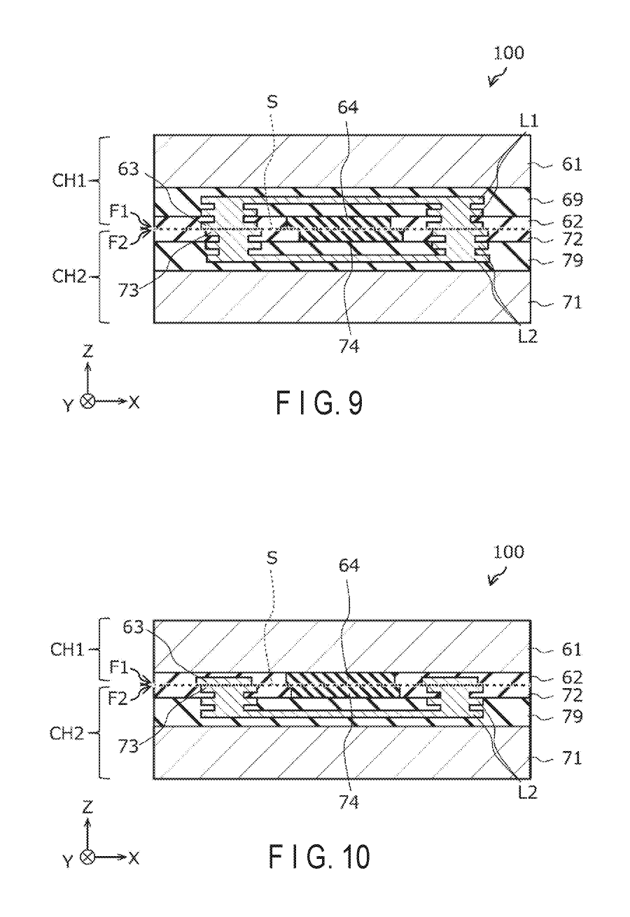

FIG. 9 illustrates a cross-sectional view of one example of a configuration of the semiconductor device 100 according to a fifth embodiment. The fifth embodiment differs from the first embodiment in that wiring layers and insulating layers are arranged inside of the semiconductor chips CH1, CH2 relative to the metal pads 63, 73.

The semiconductor chip CH1 further includes an insulating layer 69. The insulating layer 69 is arranged above the metal pad 63, that is, opposite to the surface F1 with respect to the metal pad 63. For example, the insulating layer 69 is arranged between the position of the metal pad 63 extending along the Z direction and the substrate 61. A wiring layer L1 is embedded in the insulating layer 69.

The semiconductor chip CH2 further includes an insulating layer 79. The insulating layer 79 is arranged below the metal pad 73, that is, opposite to the surface F2 with respect to the metal pad 73. For example, the insulating layer 79 is arranged between the position of the metal pad 73 extending along the Z direction and the substrate 71. A wiring layer L2 is embedded in the insulating layer 79.

The insulating layers 69, 79 may each have a multilayer structure. The wiring layers L1, L2 may each have a multilayer structure.

Wiring layers and insulating layers may be arranged inside relative to the metal pads 63, 73, as described in the fifth embodiment. With the semiconductor device 100 according to the fifth embodiment, the same effects as those provided by the first embodiment can be obtained.

### First Modification of Fifth Embodiment

FIG. 10 illustrates a cross-sectional view of one example of a configuration of the semiconductor device 100 according to a first modification of the fifth embodiment. The first modification of the fifth embodiment differs from the fifth embodiment in that the insulating layer 69 is not arranged.

In the example shown in FIG. 10, the insulating layer 79 which has been explained in the fifth embodiment is arranged but the insulating layer 69 is not arranged.

The insulating layer 69 may be arranged while the insulating layer 79 is not arranged. That is, either one of the insulating layers 69 and 79 may be omitted.

The insulating layer 69 may be omitted, as described in the first modification of the fifth embodiment. With the semiconductor device 100 according to the first modification of the fifth embodiment, the same effects as those provided by the fifth embodiment can be obtained.

### Second Modification of Fifth Embodiment

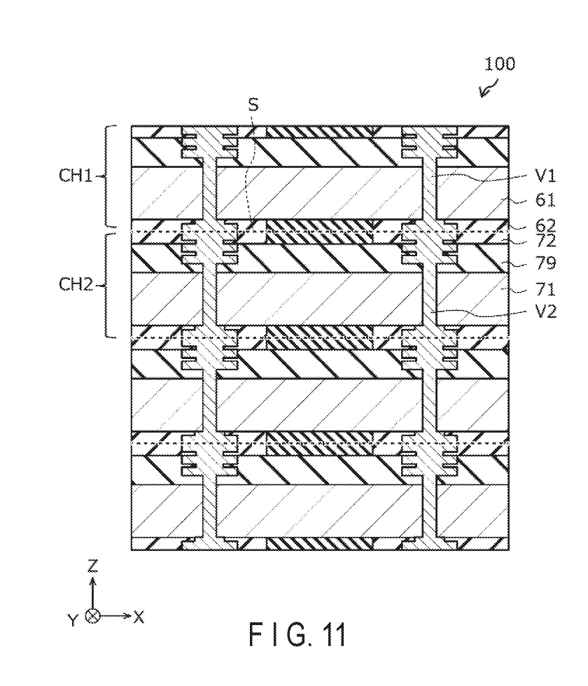

FIG. 11 illustrates a cross-sectional view of one example of a configuration of the semiconductor device 100 according to a second modification of the fifth embodiment. The second modification of the fifth embodiment differs from the fifth embodiment in that through electrodes are arranged.

In FIG. 11, metal pads are arranged on the upper surface and the lower surface of each of the substrates 61, 71. In addition to the semiconductor chips CH1, CH2, semiconductor chips bonded together are further shown.

In addition, the insulating layer 79 is arranged in FIG. 11, as explained in the first modification of the fifth embodiment, but this is a non-limiting example.

The semiconductor chip CH1 further includes a through electrode (columnar electrode) V1. The through electrode V1 is arranged so as to extend in a direction (Z direction) almost perpendicular to the surface F1 and pass through the substrate 61.

The semiconductor chip CH2 further includes a through electrode (columnar electrode) V2. The through electrode V2 is arranged so as to extend in a direction (Z direction) almost perpendicular to the surface F2 and pass through the substrate 71.

The insulating layers 69, 79 and the wiring layers L1, L2 may be formed on the bonding surface S, or may not be formed thereon.

Through electrodes may be arranged, as described in the second modification of the fifth embodiment. With the semiconductor device 100 according to the second modification of the fifth embodiment, the same effects as those provided by the fifth embodiment can be obtained.

### Sixth Embodiment

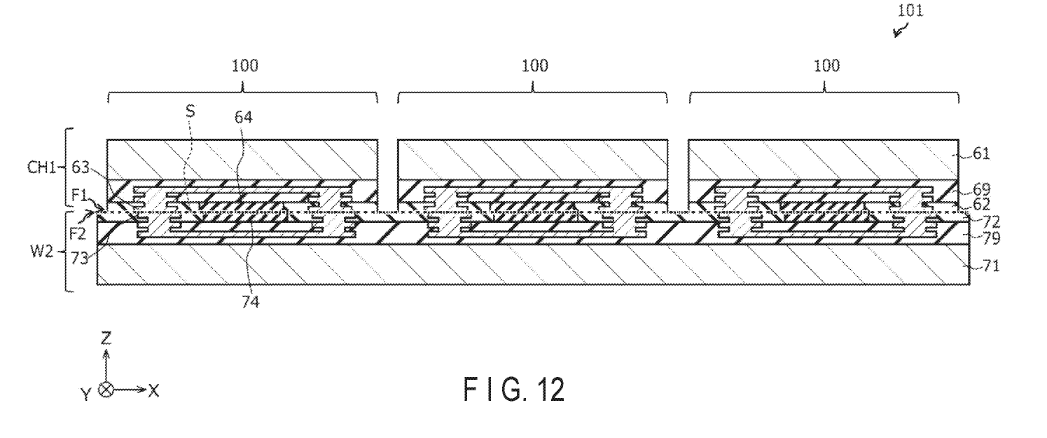

FIG. 12 illustrates a cross-sectional view of one example of a configuration of the semiconductor device 100 according to a sixth embodiment. The sixth embodiment differs from the first embodiment in that multiple singulated semiconductor chips are bonded to a wafer.

A stacked structural body 101 has a configuration in which singulation into multiple semiconductor devices 100 has not been performed.

The stacked structural body 101 includes the wafer W2, and a plurality of semiconductor chips CH2.

The wafer W2 includes the semiconductor chip CH2 that has not been singulated. Therefore, the wafer W2 includes the configuration of the semiconductor chip CH2.

The stacked structural body 101 is formed by bonding multiple singulated semiconductor chips CH1 on the wafer W2. Then, the stacked structural body 101 is singulated into multiple semiconductor devices 100.

Multiple singulated semiconductor chips may be bonded to the wafer, as described in the sixth embodiment. With the semiconductor device 100 according to the sixth embodiment, the same effects as those provided by the first embodiment can be obtained.

### First modification of Sixth Embodiment

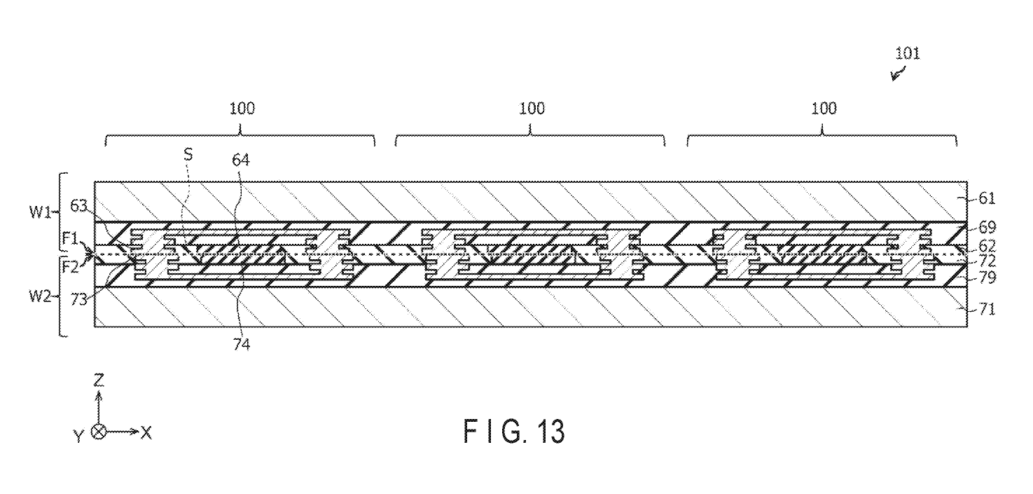

FIG. 13 illustrates a cross-sectional view of one example of a configuration of the semiconductor device 100 according to a first modification of the sixth embodiment. The first modification of the sixth embodiment differs from the sixth embodiment in that the wafers are bonded together.

The stacked structural body 101 includes the wafer W1 and the wafer W2.

The wafer W2 includes the semiconductor chip CH2 that has not been singulated. Therefore, the wafer W2 has the configuration of the semiconductor chip CH2.

The stacked structural body 101 is formed by bonding the wafer W1 with the wafer W2. Then, the stacked structural body 101 is singulated into multiple semiconductor devices 100.

The wafers may be bonded together, as described in the first modification of the sixth embodiment. With the semiconductor device 100 according to the first modification of the sixth embodiment, the same effects as those provided by the sixth embodiment can be obtained.

### Seventh Embodiment

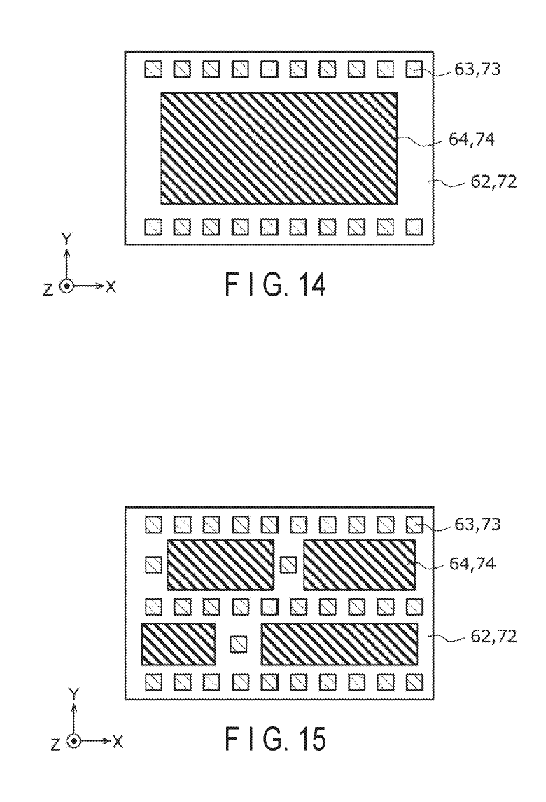

FIG. 14 illustrates a plan view of one example of a configuration of the semiconductor device 100 according to a seventh embodiment. The seventh embodiment is provided to illustrate the details of arrangement of the organic insulating films 64, 74 of the first embodiment.

In a plan view observed from the Z direction, the inorganic insulating film 62, 72 is arranged so as to (entirely) surround the organic insulating film 64, 74. That is, the organic insulating film 64, 74 is not in contact with the outer periphery of the bonding surface. Accordingly, it is possible to inhibit the organic insulating film 64, 74 from absorbing moisture and becoming a start point of detachment. As a result, the reliability can be improved.

In a plan view observed from the Z direction, the inorganic insulating film 62, 72 may be arranged to (entirely) surround the organic insulating film 64, 74, as described in the seventh embodiment. With the semiconductor device 100 according to the seventh embodiment, the same effects as those provided by the first embodiment can be obtained.

### First Modification of Seventh Embodiment

FIG. 15 illustrates a plan view of one example of a configuration of the semiconductor device 100 according to a first modification of the seventh embodiment. The first modification of the seventh embodiment differs from the seventh embodiment in that the divided organic insulating films 64, 74 are arranged.

In a plan view observed from the Z direction, the inorganic insulating films 62, 72 are arranged so as to (entirely) surround each of the dividedly arranged organic insulating films 64, 74.

The divided organic insulating films 64, 74 may be arranged, as described in the first modification of the seventh embodiment. With the semiconductor device 100 according to the first modification of the seventh embodiment, the same effects as those provided by the seventh embodiment can be obtained.

While certain embodiments have been described, these embodiments have been presented by way of example only, and are not intended to limit the scope of the inventions. Indeed, the novel devices and methods described herein may be embodied in a variety of other forms; furthermore, various omissions, substitutions, and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a first semiconductor chip that has a first surface; and
a second semiconductor chip that has a second surface and is bonded to the first semiconductor chip with the first surface and the second surface facing and in contact with each other, wherein
the first semiconductor chip includes a first metal pad, a first inorganic insulating film, and a first organic insulating film that forms at least a part of the first surface,
the second semiconductor chip includes a second metal pad, a second inorganic insulating film, and a second organic insulating film that forms at least a part of the second surface,
the first metal pad and the second metal pad are bonded to each other,
the first inorganic insulating film and the second inorganic insulating film are in contact with each other,
the first organic insulating film and the second organic insulating film are in contact with each other,
the first metal pad and the second inorganic insulating film are in contact with each other, and the second metal pad and the first inorganic insulating film are in contact with each other, and
the first inorganic insulating film and the second organic insulating film are in contact with each other, and the second inorganic insulating film and the first organic insulating film are in contact with each other.

2. The semiconductor device according to claim 1, wherein
the first metal pad and the second organic insulating film are in contact with each other, and the second metal pad and the first organic insulating film are in contact with each other.

3. The semiconductor device according to claim 1, wherein
the first semiconductor chip further includes a first barrier metal film that is provided between the first metal pad and the first inorganic insulating film and forms a part of the first surface, and
the second semiconductor chip further includes a second barrier metal film that is provided between the second metal pad and the second inorganic insulating film and forms a part of the second surface.

4. The semiconductor device according to claim 3, wherein
the first barrier metal film and the second barrier metal film are in contact with each other or bonded to each other,
the first metal pad and the second barrier metal film are in contact with each other or bonded to each other, and the second metal pad and the first barrier metal film are in contact with each other or bonded to each other, and
the first inorganic insulating film and the second barrier metal film are in contact with each other, and the second inorganic insulating film and the first barrier metal film are in contact with each other.

5. The semiconductor device according to claim 4, wherein
the first organic insulating film and the second barrier metal film are in contact with each other, and the second organic insulating film and the first barrier metal film are in contact with each other.

6. The semiconductor device according to claim 3, wherein
the first barrier metal film and the second barrier metal film are each a simple substance of Ti, Cr, Ta, W, Nb, Ru, Mo, Co, or Pd, a nitride thereof, or a composite film of two or more of these simple substances and nitrides.

7. The semiconductor device according to claim 1, wherein
a ratio of an area of the first inorganic insulating film in the first surface divided by an area of the first surface excluding an area of the first metal pad is 5% or more and 50% or less, and
a ratio of an area of the second inorganic insulating film in the second surface divided by an area of the second surface excluding an area of the second metal pad is 5% or more and 50% or less.

8. The semiconductor device according to claim 1, wherein
a ratio of an area of the first organic insulating film in the first surface divided by an area of the first surface excluding an area of the first metal pad is 50% or more and 95% or less, and
a ratio of an area of the second organic insulating film in the second surface divided by an area of the second surface excluding an area of the second metal pad is 50% or more and 95% or less.

9. The semiconductor device according to claim 1, wherein
the first semiconductor chip further includes a wiring layer and an insulating layer that are provided underneath the first surface, and
the second semiconductor chip further includes a wiring layer and an insulating layer that are provided underneath the second surface.

10. The semiconductor device according to claim 1, wherein
the first semiconductor chip further includes
a first substrate, and
a first through electrode that passes through the first substrate in a direction crossing the first surface, and
the second semiconductor chip further includes
a second substrate, and
a second through electrode that passes through the second substrate in a direction crossing the second surface.

11. The semiconductor device according to claim 1, wherein
particles are enclosed in a body formed of the first organic insulating film and the second organic insulating film that are in contact with each other.

12. The semiconductor device according to claim 1, wherein
the first metal pad and the second metal pad each contain a simple substance of Al, Cu, Au, Ag, Ni, Pd, W, Ti, Nb, Ru, Mo, Co, or Cr, a nitride thereof, a composite film of two or more thereof, or an alloy of two or more thereof.

13. The semiconductor device according to claim 1, wherein
the first inorganic insulating film and the second inorganic insulating film each contain SiO2, SiN, SiF, SiOC, SiCN, SiCOH, Al2O3, or AlN.

14. The semiconductor device according to claim 1, wherein
the first organic insulating film and the second organic insulating film each contain an epoxy-based, phenol-based, polyimide-based, polyamide-based, acrylic-based, polybenzoxazole (PBO)-based, silicone-based, or benzocyclobutene-based resin.

15. The semiconductor device according to claim 1, wherein
the first chip comprises a semiconductor memory cell array, and
the second chip comprises a control circuit configured to control operations of the semiconductor memory cell array.

16. The semiconductor device according to claim 15, wherein
the first metal pad is electrically connected to a bit line of the semiconductor memory cell array, and
the second metal pad is electrically connected to a transistor of the control circuit.

17. The semiconductor device according to claim 1, wherein
on the first surface, the first organic insulating film forms a single region that is entirely surrounded by the first inorganic insulating film, and
on the second surface, the second organic insulating film forms a single region that is entirely surrounded by the second inorganic insulating film.

18. The semiconductor device according to claim 1, wherein
on the first surface, the first organic insulating film forms a plurality of regions, each of which is entirely surrounded by the first inorganic insulating film, and
on the second surface, the second organic insulating film forms a plurality of regions, each of which is entirely surrounded by the second inorganic insulating film.

19. A method for manufacturing a semiconductor device, comprising:
forming a first metal pad, a first inorganic insulating film, and a first organic insulating film on a first surface of a first semiconductor chip, and forming a second metal pad, a second inorganic insulating film, and a second organic insulating film on a second surface of a second semiconductor chip;
planarizing the first surface to expose the first metal pad, the first inorganic insulating film, and the first organic insulating film therefrom, and planarizing the second surface to expose the second metal pad, the second inorganic insulating film, and the second organic insulating film therefrom;
performing plasma treatment on the first surface, and performing plasma treatment on the second surface; and
bonding the first semiconductor chip and the second semiconductor chip together with the first surface and the second surface facing and in contact with each other.

20. The method according to claim 19, further comprising
adding a hydroxyl group to the first surface and adding a hydroxyl group to the second surface before bonding the first semiconductor chip and the second semiconductor chip together.
